(19) United States
(12) Patent Application Publication
(10) Pub. No.: US 2026/0202757 A1
(43) Pub. Date: Jul. 16, 2026

(54) METHODS AND SYSTEMS FOR DETERMINING RETICLE DEFORMATION

(71) Applicant: ASML NETHERLANDS B.V., Veldhoven (NL)

(72) Inventors: Amin KARAMNEJAD, Eindhoven (NL); Raaja Ganapathy SUBRAMANIAN, Maarheeze (NL); Bearrach MOEST, Eindhoven (NL); Alexander Alexandrovich DANILIN, Eindhoven (NL)

(73) Assignee: ASML NETHERLANDS B.V., Veldhoven (NL)

(21) Appl. No.: 19/135,059

(22) PCT Filed: Dec. 6, 2023
(86) PCT No.: PCT/EP2023/084626

§ 371 Date: Jun. 2, 2025

Related U.S. Application Data
(60) Provisional application No. 63/435,500, filed on Dec. 27, 2022.

(51) Int. Cl. G03F 7/00; G03F 1/82

(52) U.S. Cl. CPC G03F 7/70504; G03F 1/82; G03F 7/70525; G03F 7/7085

(57) ABSTRACT

A computer system configured to: model, using boundary conditions that are dependent on a first state of a reticle during a first time period, the deformation of the reticle during the first time period; model, using boundary conditions that are dependent on a second state of the reticle during a second time period, the deformation of the reticle during the second time period; and control the operation of a lithographic process in dependence on the modelled deformation of the reticle, wherein: the first state of the reticle is different from the second state of the reticle; and the modelled deformation of the reticle at the start of the second time period is based on the modelled deformation of the reticle at the end of the first time period.

### CROSS-REFERENCE TO RELATED APPLICATION

This application claims priority of a U.S. application 63/435,500 which was filed on 27 Dec. 2022 and which is incorporated herein in its entirety by reference.

### FIELD

The present disclosure relates to techniques for improving the accuracy of the prediction of the deformation of a reticle. Process corrections may be determined and applied in dependence on the determined deformation to reduce reticle induced errors in a lithographic process.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern of a patterning device (e.g., a mask, a reticle) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, deep ultraviolet (DUV) radiation with a wavelength of 157 nm or 193 nm or 248 nm.

A lithographic apparatus can include a reticle stage to hold a patterning device (e.g., a reticle) to transfer a pattern to a substrate. Reticle heating and/or cooling can cause changes in reticle properties that can affect the radiation beam path (e.g., focus) and cause distortions in the patterned substrate (e.g., overlay errors). Changes in reticle properties can be modeled and corrected with a reticle heating model. Known reticle heating models rely on a sensor-based approach to calibrate the reticle heating model with a reticle temperature sensor (RTS) and require a calibration lot of production wafers. In some examples, this approach can be inaccurate and inefficient since the RTS can exhibit errors, introduce unnecessary delays, and require rework of production wafers.

The shape of a reticle may also be deformed by other effects, such as the applied clamping force to the reticle. If not compensated for, all reticle shape deformation may increase distortions in the patterned substrate (e.g., overlay errors).

### SUMMARY

There is a general need to improve on known techniques for the determination of the deformation shape of a reticle. Process corrections may be determined and applied in dependence on the determined deformation to reduce reticle induced errors in a lithographic process. This may avoid the rework of production substrates, and/or increase the fabrication throughput and yield of lithographic processes.

According to a first aspect of the invention, there is provided a computer system configured to: model, using boundary conditions that are dependent on a first state of a reticle during a first time period, the deformation of the reticle during the first time period; model, using boundary conditions that are dependent on a second state of the reticle during a second time period, the deformation of the reticle during the second time period; and control the operation of a lithographic process in dependence on the modelled deformation of the reticle; wherein: the first state of the reticle is different from the second state of the reticle; and the modelled deformation of the reticle at the start of the second time period is based on the modelled deformation of the reticle at the end of the first time period.

According to a second aspect of the invention, there is provided a method comprising: modelling, using boundary conditions that are dependent on a first state of a reticle during a first time period, the deformation of the reticle during the first time period; modelling, using boundary conditions that are dependent on a second state of the reticle during a second time period, the deformation of the reticle during the second time period; and controlling the operation of a lithographic process in dependence on the modelled deformation of the reticle; wherein: the first state of the reticle is different from the second state of the reticle; and the modelled deformation of the reticle at the start of the second time period is based on the modelled deformation of the reticle at the end of the first time period.

According to a third aspect of the invention, there is provided a system comprising: a computer system according to the first aspect; and a lithographic apparatus; wherein the computer system is configured to control the operation of lithographic apparatus.

According to a fourth aspect of the invention, there is provided a device manufacturing method using a lithographic process, the device manufacturing method comprising the method according to the second aspect.

According to a fifth aspect of the invention, there is provided a non-transitory computer readable medium program comprising computer readable instructions configured to cause a processor to control a lithographic apparatus according to the method of the second aspect.

Implementations of any of the techniques described herein may include an EUV light source, a DUV light source, a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic illustration of a lithographic apparatus, according to an exemplary aspect.

FIG. 2A is a schematic illustration of a lithographic cell, according to an exemplary aspect.

FIG. 2B is a schematic illustration of holistic lithography including a computer system to optimize a lithographic process, according to an exemplary aspect.

FIG. 3A is a schematic bottom perspective illustration of a reticle stage and a reticle, according to an exemplary aspect.

FIG. 3B is a schematic bottom plan illustration of the reticle stage shown in FIG. 3A.

FIG. 4A is a schematic top perspective illustration of a reticle exchange apparatus, according to an exemplary aspect.

FIG. 4B is a schematic partial cross-sectional illustration of the reticle exchange apparatus shown in FIG. 4A.

FIG. 5 schematically shows the overlay error that may be caused by the temperature of the reticle if processes for not correcting this source of overlay error are not performed.

FIG. 6 schematically shows a modelled magnitude of the deformation by a reticle deformation model according to embodiments.

FIG. 7 shows a flowchart of a process according to an embodiment.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to effect such feature, structure, or characteristic in connection with other aspects whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

The term “parasitic thermal effects” as used herein indicates induced or internal stresses and/or deformations of a reticle, for example, due to heating and/or cooling the reticle (e.g., by resistive heating, gas flow cooling, exposing the reticle to a dose of radiation, etc.) or mechanical pressures and/or deformations from clamping and/or holding the reticle on the reticle stage.

The term “non-production substrate” as used herein indicates a substrate (e.g., a wafer) that is not part of a production lot and is not fabricated by a lithographic process into a device (e.g., an IC chip). For example, a non-production substrate can be a chuck temperature conditioning (CTC) wafer or calibration wafer for a reticle calibration method, for example, to calibrate a reticle heating model and to acclimate the reticle by exposing the reticle and the CTC wafer to a dose of radiation and measuring a reticle alignment and/or a reticle temperature.

The term “production substrate” as used herein indicates a substrate (e.g., a wafer) that is part of a production lot and is fabricated by a lithographic process into a device (e.g., an IC chip). For example, a production substrate can be a wafer (e.g., silicon) for fabrication and inline real-time calibration of a reticle heating model, for example, by exposing the reticle and the wafer to a dose of radiation and measuring a reticle alignment and/or a reticle temperature.

The term “reticle heating model” as used herein indicates a modal deformation approach (e.g., analysis of different reticle mode shapes) to determine reticle heating effects based on reticle alignment and/or reticle shape deformations and a finite element model (FEM) (e.g., COMSOL). For example, the reticle heating model can be deterministic (e.g., no random future states) or non-deterministic (e.g., including random future states) reticle heating effects. Further, the reticle heating model can be deemed a reticle heating execution algorithm (RHEA) that uses inline modal calibrations to determine the baseline reticle heating dynamics. The reticle heating model can be calibrated by exposing a reticle and a non-production substrate to a dose of radiation for inline real-time calibration of the reticle heating model. In some aspects, for example, the reticle heating model can be calibrated by exposing a reticle and a production substrate to a dose of radiation for inline real-time calibration of the reticle heating model. Other reticle heating models utilize a sensor-based approach (e.g., using RTS measurements) to calibrate the reticle heating model. This is described in further detail in U.S. Pat. Nos. 10,429,749, 10,281,825, and U.S. Patent Application Publication No. 2020/0166854, which are incorporated by reference herein in their entireties.

Reticle heating causes changes in reticle properties that can affect the radiation path and cause fabrication errors (e.g., overlay). Reticle mechanical deformations (e.g., based on reticle temperature) can be calculated and decomposed into k-parameters. Each thermo-mechanical mode (e.g., eigenvector) can be modeled in time using modal participation factor μ and time constant τ. Measured overlay and/or alignment can be used to model the related k-parameter drifts, which can be used to calculate adjustments to the feed-forward parameters μ and τ. The reticle heating model can also include adjusting feed-forward parameters μ and τ. This is described in further detail in U.S. Pat. No. 10,429,749, U.S. Patent Application Publication No. 2020/0166854, and PCT Patent Application Publication No. 2021/043519, which are incorporated by reference herein in their entireties.

The term “finite element model” or “FEM” as used herein indicates a method for numerically solving differential equations arising in the reticle heating model (e.g., heat transfer equations, structural analysis equations, fluid flow equations, etc.). For example, baseline reticle heating dynamics can be analyzed with the FEM through finite element analysis. This is described in further detail in U.S. Pat. Nos. 10,429,749, 10,281,825, and U.S. Patent Application Publication No. 2020/0166854, which are incorporated by reference herein in their entireties.

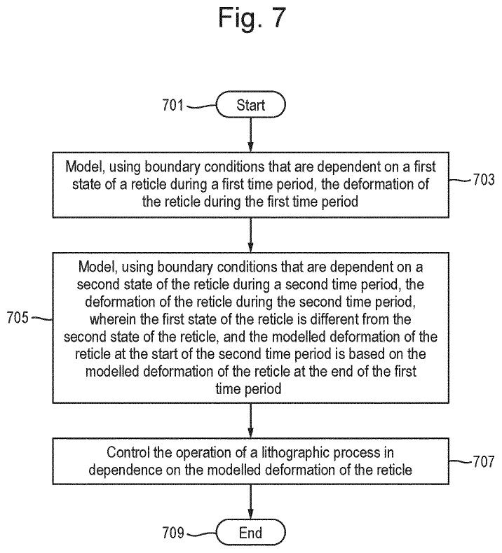

The term “key performance indicators” or “KPIs” or “k-parameters” as used herein indicates coefficients of polynomials that are fit to distortions of reticle alignment marks and/or edge alignment marks. The k-parameters parameterize the distortion of the imaging across the field of each substrate. For example, each k-parameter can describe a certain image distortion component (e.g., scaling error, barrel distortion, pincushion distortion, etc.). For example, two important k-parameters are k4 (e.g., k4/my shown in FIG. 7) that represents distortion in Y-axis magnification and k18 (e.g., k18/cshpy shown in FIG. 8) that represents distortion in Y-axis barrel shape. The k-parameters can be used as input to a lithographic process (e.g., lithographic apparatus LA, lithographic cell LC, control system CL) to correct the distortion. This is described in further detail in U.S. Pat. No. 10,429,749, U.S. Patent Application Publication No. 2020/0166854, and PCT Patent Application Publication No. 2021/043519, which are incorporated by reference herein in their entireties.

Aspects of the disclosure may be implemented in hardware, firmware, software, or any combination thereof. Aspects of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such aspects in more detail, however, it is instructive to present example environments in which aspects of the present disclosure may be implemented.

### Exemplary Lithographic System

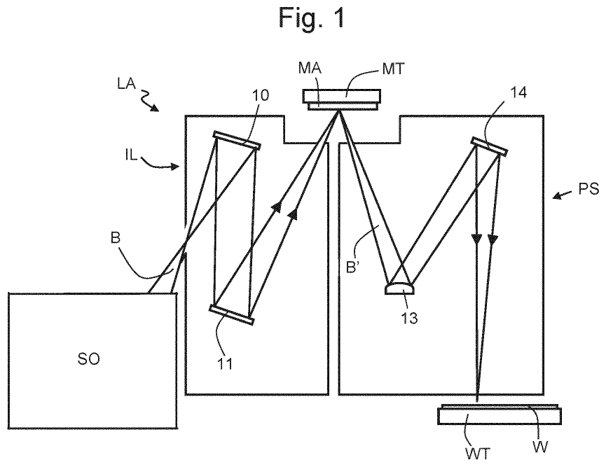

FIG. 1 shows a lithographic system comprising a radiation source SO and a lithographic apparatus LA. The radiation source SO is configured to generate an EUV and/or a DUV radiation beam B and to supply the EUV or DUV radiation beam B to the lithographic apparatus LA. The lithographic apparatus LA comprises an illumination system IL, a support structure MT (e.g., a mask table, a reticle table, a reticle stage) configured to support a patterning device MA (e.g., a mask, a reticle), a projection system PS, and a substrate table WT configured to support a substrate W.

The illumination system IL is configured to condition the EUV or DUV radiation beam B before the EUV or DUV radiation beam B is incident upon the patterning device MA. Thereto, the illumination system IL may include a faceted field mirror device 10 and a faceted pupil mirror device 11. The faceted field mirror device 10 and faceted pupil mirror device 11 together provide the EUV or DUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV or DUV radiation beam B interacts with the patterning device MA. This interaction may be reflective (as shown), which may be preferred for EUV radiation. This interaction may be transmissive, which may be preferred for DUV radiation. As a result of this interaction, a patterned EUV or DUV radiation beam B′ is generated. The projection system PS is configured to project the patterned EUV or DUV radiation beam B′ onto the substrate W. For that purpose, the projection system PS may comprise a plurality of mirrors 13, 14 which are configured to project the patterned EUV or DUV radiation beam B′ onto the substrate W held by the substrate table WT. The projection system PS may apply a reduction factor to the patterned EUV or DUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV or DUV radiation beam B′, with a pattern previously formed on the substrate W.

### Exemplary Lithographic Cell

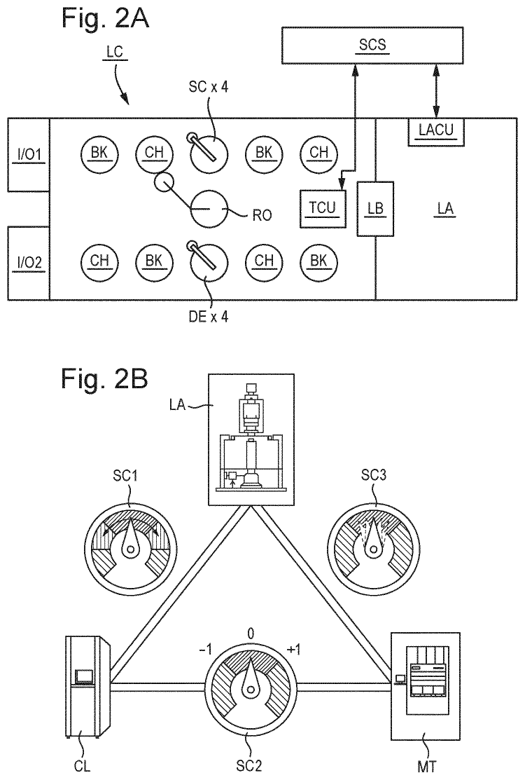

FIG. 2A shows a lithographic cell LC, also sometimes referred to as a lithocell or cluster. Lithographic apparatus LA may form part of lithographic cell LC. Lithographic cell LC may also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus LA. These devices, which are often collectively referred to as the track, are under the control of a track control unit TCU which is itself controlled by a supervisory control system SCS, which also controls the lithographic apparatus LA via lithography control unit LACU. Thus, the different apparatuses can be operated to maximize throughput and processing efficiency.

In order for the substrates W exposed by the lithographic apparatus LA to be exposed correctly and consistently, it is desirable to inspect substrates to measure properties of patterned substrates, for example, overlay errors between subsequent layers, line thicknesses, critical dimensions (CD), etc. For this purpose, inspection tools (e.g., metrology tool MT) may be included in lithographic cell LC and/or lithographic apparatus LA. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus or metrology tool MT, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of lithographic cell LC, integrated into lithographic apparatus LA, and/or be a stand-alone device. The inspection apparatus may measure the properties on a latent image (e.g., image in a resist layer after the exposure), on a semi-latent image (e.g., image in a resist layer after a post-exposure bake step), on a developed resist image (e.g., image in which the exposed or unexposed parts of the resist have been removed), or on an etched image (e.g., image after a pattern transfer step, such as etching).

### Exemplary Computer System

FIG. 2B shows a computer system CL, also referred to as a controller or processor. Computer system CL may be part of lithographic cell LC, integrated into lithographic apparatus LA, and/or be a stand-alone device. Computer system CL is configured to optimize a lithographic process, for example, calibrate a reticle heating model. Typically the patterning process in lithographic apparatus LA is one of the most critical steps in the processing, which requires high accuracy of dimensioning and placement of structures on the substrate W. To ensure this high accuracy, three systems can be combined in a so-called “holistic” control environment as schematically depicted in FIG. 2B. As shown in FIG. 2B, the “holistic” environment can include lithographic apparatus LA, computer system CL, and metrology tool MT. For example, lithographic apparatus LA (a first system) can be connected to computer system CL (a second system) and metrology tool MT (a third system).

The key of such holistic lithography is to optimize the cooperation between these three systems to optimize a lithographic process, for example, to enhance the overall process window and provide tight controls loops to ensure that the patterning performed by lithographic apparatus LA stays within a process window. The process window defines a range of process parameters, for example, dose, focus, overlay, etc., within which a specific manufacturing process yields a defined result, for example, a functional semiconductor device-typically within which the process parameters in the lithographic process or patterning process are allowed to vary.

Computer system CL may, for example, use (e.g., part of) the design layout to be patterned to predict which resolution enhancement techniques to use and to perform computational lithography simulations and calculations, for example, to determine which mask layout and lithographic apparatus settings achieve the largest overall process window of the patterning process (shown in FIG. 2B by the double arrow in the first scale SC1). Typically, the resolution enhancement techniques are arranged to match the patterning possibilities of lithographic apparatus LA. Computer system CL may also be used to detect where within the process window lithographic apparatus LA is currently operating (e.g., using input from metrology tool MT) to predict whether defects may be present, for example, due to sub-optimal processing (shown in FIG. 2B by the arrow pointing “0” in the second scale SC2).

Metrology tool MT may provide input to computer system CL, for example, to enable accurate simulations and predictions. For example, metrology tool MT may provide alignment information. Metrology tool MT may provide feedback (e.g., via computer system CL) to lithographic apparatus LA to identify possible drifts, for example, in a calibration status of lithographic apparatus LA (shown in FIG. 2B by the multiple arrows in the third scale SC3). In lithographic processes, it is desirable to make frequent measurements of the structures created, for example, for process control and verification. Different types of metrology tools MT can be used, for example, to measure one or more properties relating to lithographic apparatus LA, a substrate W to be patterned, and/or reticle alignment. This is described in further details in U.S. Pat. No. 11,099,319 and PCT Patent Application Publication No. 2021/043519, which are incorporated by reference herein in their entireties.

### Exemplary Reticle Stage and Reticle

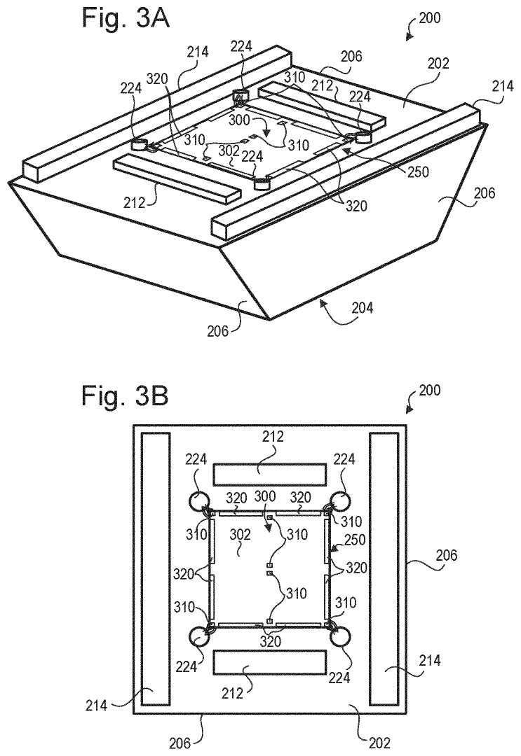

FIGS. 3A and 3B show schematic illustrations of reticle stage 200, according to exemplary aspects. FIG. 3A is a schematic bottom perspective illustration of reticle stage 200 and reticle 300, according to an example aspect. FIG. 3B is a schematic bottom plan illustration of reticle stage 200 and reticle 300 shown in FIG. 3A.

Reticle stage 200 (e.g., support structure MT) can be used in a lithographic apparatus (e.g., lithographic apparatus LA) to hold a patterning device (e.g., patterning device MA). Reticle stage 200 can include bottom stage surface 202, top stage surface 204, side stage surfaces 206, clamp 250, reticle cage 224, and/or reticle 300. In some aspects, reticle stage 200 with reticle 300 can be implemented in lithographic apparatus LA. For example, reticle stage 200 can be support structure MT in lithographic apparatus LA. In some aspects, reticle 300 can be disposed on bottom stage surface 202 and held by clamp 250. For example, as shown in FIGS. 3A and 3B, reticle 300 can be disposed on clamp 250 (e.g., an electrostatic clamp) at a center of bottom stage surface 202 with reticle frontside 302 facing perpendicularly away from bottom stage surface 202. In some aspects, reticle cage 224 can be disposed on bottom stage surface 202. For example, as shown in FIGS. 3A and 3B, reticle 300 can be disposed at a center of bottom stage surface 202 and secured by reticle cages 224 adjacent to each corner of reticle 300.

In some lithographic apparatuses, for example, lithographic apparatus LA, reticle stage 200 with clamp 250 can be used to hold and position reticle 300 for scanning or patterning operations. In some aspects, as shown in FIGS. 3A and 3B, reticle stage 200 can include first encoder 212 and second encoder 214 for positioning operations. For example, first and second encoders 212, 214 can be interferometers. First encoder 212 can be attached along a first direction, for example, a transverse direction (i.e., X-direction) of reticle stage 200. And second encoder 214 can be attached along a second direction, for example, a longitudinal direction (i.e., Y-direction) of reticle stage 200.

As shown in FIGS. 3A and 3B, reticle 300 can include reticle frontside 302, alignment mark 310, and/or edge alignment mark 320. Alignment mark 310 is configured to measure a reticle alignment between reticle 300 and a substrate (e.g., substrate W, non-production substrate, production substrate). In some aspects, as shown in FIGS. 3A and 3B, one or more alignment marks 310 can be disposed in the corners and/or the center of reticle 300 for an RA measurement. Edge alignment mark 320 is configured to measure a reticle shape deformation of reticle 300 due to thermal expansion when reticle 300 is not within a predetermined temperature (e.g., at 22° C.±0.2° C.). In some aspects, as shown in FIGS. 3A and 3B, one or more edge alignment marks 320 can be disposed along the perimeter edges (e.g., horizontal and vertical edges) of reticle 300 for a reticle shape deformation (RSD) measurement. In some aspects, the results of the RA measurement and/or the RSD measurement can be converted to a reticle temperature, for example, by a FEM that solves for temperature based on reticle alignment and/or reticle deformation.

### Exemplary Reticle Exchange Apparatus

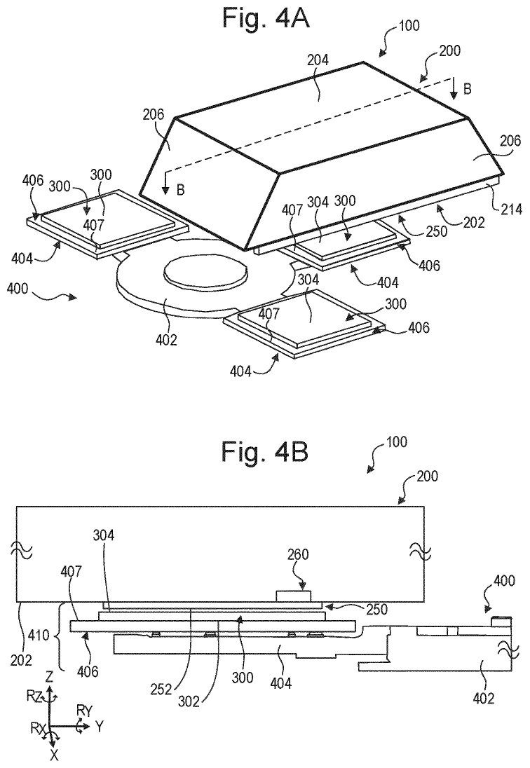

FIGS. 4A and 4B show schematic illustrations of reticle exchange apparatus 100, according to exemplary aspects. FIG. 4A is a schematic top perspective illustration of reticle exchange apparatus 100, according to an exemplary aspect. FIG. 4B is a schematic partial cross-sectional illustration of reticle exchange apparatus 100 shown in FIG. 4A.

Reticle exchange apparatus 100 can be configured to reduce reticle exchange time and thermal stresses in reticle 300 to increase overall throughput, for example, in lithographic apparatus LA. In some aspects, reticle exchange apparatus 100 can reduce stress in reticle 300 by removing reticle 300 from reticle stage 200 to in-vacuum robot (IVR) 400. For example, reticle exchange apparatus 100 can quickly unclamp reticle 300 from reticle cages 224 and clamp 250 and transfer reticle 300 to IVR 400 to release thermal stress in reticle 300. In some aspects, reticle exchange apparatus 100 can reduce stress in reticle 300 and increase throughput by unclamping and transferring reticle 300 from reticle stage 200 to IVR 400 and quickly returning and clamping reticle 300 back to reticle stage 200. As shown in FIGS. 4A and 4B, reticle exchange apparatus 100 can include reticle stage 200, clamp 250, and IVR 400.

IVR 400 can include reticle handler 402 with one or more reticle handler arms 404. In some aspects, reticle handler 402 can be a rapid exchange device (RED), which is configured to efficiently rotate and minimize reticle exchange time. Reticle handler arm 404 can include reticle baseplate 406 configured to hold an object, for example, reticle 300. In some aspects, reticle baseplate 406 can be an extreme ultraviolet inner pod (EIP) for reticle 300. Reticle baseplate 406 includes reticle baseplate frontside 407, and reticle 300 includes reticle backside 304.

As shown in FIGS. 4A and 4B, reticle baseplate 406 can hold reticle 300 such that reticle baseplate frontside 407 and reticle backside 304 each face bottom stage surface 202 and clamp frontside 252. For example, reticle baseplate frontside 407 and reticle backside 304 can be facing perpendicularly away from bottom stage surface 202 and clamp frontside 252. As shown in FIG. 4B, reticle exchange apparatus 100 can include reticle exchange area 410, which is the cross-sectional area between clamp 250, reticle 300, reticle baseplate 406, and reticle handler arm 404 during a reticle exchange process.

In one example, during a reticle exchange process, reticle handler arm 404 of reticle handler 402 positions reticle 300 on reticle baseplate 406 towards clamp 250 in reticle exchange area 410. As described above, a reticle handoff from reticle handler 402 to clamp 250 and vice-versa can release thermal stress in reticle 300 and reduce parasitic thermal effects in reticle 300.

### Reticle Deformation Determination

The operating conditions of a reticle 300 may cause a deformation of the shape of the reticle 300. In particular, the shape of a reticle 300 may be deformed due to the reticle 300 being heated by each exposure process that is performed with the reticle 300 during a lithographic process.

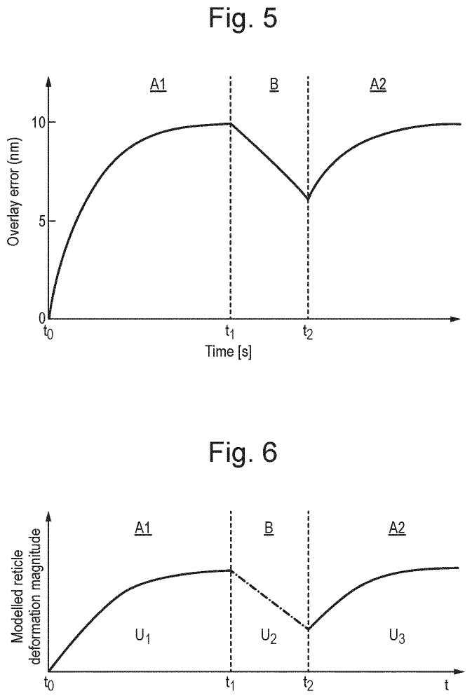

The effect of temperature-induced deformation of a reticle 300 is described below with reference to FIG. 5.

FIG. 5 schematically shows the overlay error that may be caused by the temperature-induced deformation of the reticle 300 if processes for correcting this source of overlay error are not performed. The magnitude of the overlay error shown on the y-axis is exemplary and the actual magnitude of the overlay error may be more, or less, than what is shown.

Time period A1 starts at t₀ and ends at t₁. At t₀, an appropriately temperature conditioned reticle 300 is clamped to a reticle stage 200. The reticle 300 may be referred to as being in a cold state. During the time period A1, the reticle 300 is illuminated during exposure processes and it is heated. The effect of the heating is to increase the shape deformation of the reticle 300 and this increases the magnitude of the overlay error. At time t₁, the reticle 300 may be referred to as being in a hot state.

Time period B starts at t₁ and ends at t₂. During the time period B, the reticle 300 is not used and so it cools down. The shape deformation of the reticle 300 reduces as the reticle 300 cools towards to the ambient temperature and the cold state of the reticle 300. The effect of the cooling is to reduce the expected magnitude of the overlay error were the reticle 300 to be used.

Time period A2 starts at t₂. In the time period A2, the reticle 300 is re-used and it is heated by exposure processes. The effect of the heating is to increase the shape deformation of the reticle 300 and this increases the magnitude of the overlay error.

As shown in FIG. 5, the time period B may be insufficiently long for the reticle 300 to cool down to the same cold state as at the start of time period A1, i.e. at t₀. The temperature-induced shape deformation of the reticle 300 is therefore larger at t₂ than at t₀.

As described earlier, it is known to determine the deformation of a reticle 300 in dependence on one or more reticle alignment, RA, measurements. A reticle 300 may comprise edge alignment marks 320 that may be measured in one or more RA measurements. The shape deformation of reticle 300 due to thermal expansion may be determined in dependence on the one or more RA measurements.

It is also known for a reticle heating controller to use a thermomechanical finite element model (FEM) to determine how the shape deformation of a reticle 300 changes during time period that the reticle is used. For example, the inputs to the model may include parameters related to the use and properties of the reticle 300, such as input energy, the field size, the locations of features on the reticle 300, and the initial conditions of a reticle 300 that is in a cold state. The output of the model may be a determination of the current deformation of a reticle shape. The current deformation of a reticle shape may differ from the deformation measured by the most recent RA measurement(s) if there has been a temperature change of the reticle 300.

In dependence on the determined current deformation of the reticle shape, the configuration and/or operation of processes performed with the reticle 300 may be changed to at least partially compensate for the overlay error that would otherwise be caused by the current deformation of the reticle shape.

A problem with known reticle deformation models is that they do not accurately model the situation shown in FIG. 5, which may be referred to as an ABA lot sequence problem, a fast lost transition problem, or a hot reticle re-clamp problem. Known reticle deformation models only model the deformation of the reticle 300 when the reticle 300 is used in lithographic processes. The deformation of the reticle 300 is therefore only modelled in time periods A1 and A2 in FIG. 5. The model assumes that the reticle 300 is in a cold state at the start of each use of the reticle 300. However, as described above, this may be an incorrect assumption because when a reticle 300 is re-used, such as at t₂ in FIG. 5, the reticle 300 may still be hot. The incorrect assumption that a reticle 300 is in a cold state at the start of each use of the reticle 300 is a source of error in known techniques for modelling the deformation of the reticle 300. The determined process corrections for compensating for the deformation of the reticle 300 will consequently also be inaccurate.

Embodiments provide a reticle deformation model that improves on known techniques.

The reticle deformation model according to embodiments models the deformation of the reticle 300 during, and also between, uses of the reticle 300. For example, the deformation of the reticle 300 during time period B in FIG. 5 may be modelled and used to improve the determination of the reticle deformation at the start of the next re-use of the reticle 300, i.e. at time t₂.

The reticle 300 is clamped to a reticle stage 200 whenever the reticle 300 is used in a lithographic process. Accordingly, in time periods A1 and A2 in FIG. 5, a clamp 250 applies a clamping force to the reticle 300 so as to secure the reticle 300 to the reticle stage 200. The applied clamping force may generate thermomechanical stresses within the reticle 300. When the reticle 300 is not used in a lithographic process, such as in time period B in FIG. 5, the same clamping force is not applied to the reticle 300 and this may release thermomechanical stresses in the reticle 300. The application, and release, of the clamping force during the different time periods may therefore also change the shape deformation of the reticle 300.

Embodiments provide a new reticle heating model for modelling the deformation of the reticle 300 both when the reticle 300 is used and also between uses of the reticle 300. The reticle heating model according to embodiments uses boundary conditions that are dependent on whether or not a clamping force is applied to the reticle 300. Advantageously, the deformation of a reticle 300 may be more accurately modelled, in particular when fast lot transitions occur.

When a reticle 300 is clamped to a reticle stage 200, the coordinate system shown in FIG. 4B may be applied so that the plane of the reticle 300 lies in the x-y plane. The clamping force that secures the reticle 300 to the reticle stage 200 may be applied along the z-axis. In a model of the reticle deformation, the z-axis thermomechanical and/or thermal boundary conditions are dependent on whether or not a clamping force is applied to the reticle 300.

Embodiments provide a reticle deformation model that may be FEM, such as a thermomechanical FEM. The model may be similar to known reticle deformation models to the extent that it models the shape deformation of the reticle 300 in dependence on modelled thermal properties of the reticle 300. Embodiments differ from known techniques by the reticle deformation model modelling the deformation between uses of the reticle 300. To model the deformation of the reticle 300 between uses, the model according to embodiments may use different thermal and mechanical boundary conditions in dependence on whether a reticle 300 is clamped to a reticle stage 200. Advantageously, the effect on the reticle deformation of when the clamping force is applied is included in the reticle deformation model.

The applied reticle deformation model when a clamping force is applied to a reticle 300 may be referred to as U_{clamped reticle}(X, t), where X is the (x,y,z) coordinates of a point on the reticle and t is a time reference of the determined deformation.

The applied reticle deformation model when a clamping force is not applied to a reticle 300 may be referred to as U_{free reticle}(X, t), where X is the (x,y,z) coordinates of a point on the reticle and t is a time reference of the determined deformation.

FIG. 6 schematically shows the modelled magnitude of the deformation, by the reticle deformation model according to embodiments, when the fast lot transition shown in FIG. 5 is performed with the reticle 300. The deformation is determined by either U₁(X, t), U₂(X, t) or U₃(X, t), as shown below:

$$\begin{matrix}{U}_{1} ( X , t ) = {U}_{clamped reticle} ( X , t - {t}_{0} ) & for {t}_{0} \leq t < {t}_{1} \\ {U}_{2} ( X , t ) = {U}_{1} ( X , {t}_{1} ) + {U}_{free reticle} ( X , t - {t}_{1} ) & for {t}_{1} \leq t < {t}_{2} \\ {U}_{3} ( X , t ) = {u}_{clamped reticie} ( X , t - {t}_{2} ) + {U}_{2} ( X , {t}_{2} ) & for t \geq {t}_{2}\end{matrix}$$

The times at which a reticle 300 is either clamped to a reticle stage 200 or unclamped from the reticle stage 200, i.e. t₀, t₁, t₂, are the times that the boundary conditions for the reticle 300 change. The times t₀, t₁, t₂ may be determined from data on the handling of the reticle 300 and/or operational data of the system.

The model determines the deformation of the reticle shape in dependence on the current clamping state of the reticle 300 and the effect of previous clamping states on the deformation. When the clamping state of the reticle 300 changes (i.e. from clamped to unclamped at t₁, and from unclamped to clamped at t₂), the boundary conditions of the reticle deformation model are changed. When the boundary conditions of the reticle deformation model are changed, the final determined reticle deformation with the previously used boundary conditions is used as a starting deformation of the reticle heating model with the new boundary conditions.

Accordingly, as shown by the above equations, in time period B, when no clamping force is applied to the reticle 300, the reticle deformation is determined by U₂(X, t). The overall reticle deformation is determined in dependence on both the previously determined deformation when the reticle 300 was clamped, which is U₁(X, t₁), and also the time dependent modelling of the current deformation, which is U_{free reticle}(X, t−t₁).

Similarly, as also shown by the above equations, in time period A2, when a clamping force is applied to the reticle 300, the reticle deformation is determined by U₃(X, t). The overall reticle deformation is determined in dependence on both the previously determined deformation when the reticle 300 was not clamped, which is U₂(X, t₂), and also the time dependent modelling of the current deformation, which is U_{clamped reticle}(X, t−t₂).

The reticle deformation model according to embodiments may be used between measurements of the deformation of the reticle shape by RA measurements. In particular, an initial deformation state of a reticle 300 may be determined from a first set of one or more RA measurements. The initial deformation state of a reticle 300 may be used as the initial reticle shape by the reticle deformation model according to embodiments. The reticle deformation model according to embodiments may then be used to determine the current deformation of the reticle 300 until a second set of one or more RA measurements is used to determine the reticle deformation. The deformation determined by the second set of one or more RA measurements may then be used as a new starting reticle shape by the reticle deformation model.

Embodiments improve on known techniques by providing a reticle deformation model that is dependent on the current reticle clamping state as well as the effect of the previous reticle clamping states on the reticle deformation. Embodiments include determining process corrections that may be applied in dependence on the determined shape deformation of the reticle 300 so as to at least partially compensate the effects of the deformation. For example, the applied process corrections may include changing one or more of the location of a stage lens, changing a parameter of a scanning lens, and moving an object stage. The improvement in the accuracy of the reticle deformation determination results in improved process corrections being determined and applied. Embodiments thereby provide improved overlay performance, i.e. a lower overlay error, than known techniques.

Embodiments include controlling a reticle heating controller in dependence on the deformation as determined by the reticle deformation model according to embodiments.

A further advantage of the reticle deformation model according to embodiments is that, when the model is a FEM, the model parameters are based on physical principles rather than the model being a ‘black box’. This allows the model to be tuned given any hardware changes, such as changes of the reticle 300 and/or clamp 250 types.

FIG. 7 shows a flowchart of a process according to an embodiment.

In step 701, the method starts.

In step 703, the method models, using boundary conditions that are dependent on a first state of a reticle during a first time period, the deformation of the reticle during the first time period.

In step 705, the method models, using boundary conditions that are dependent on a second state of the reticle during a second time period, the deformation of the reticle during the second time period, wherein the first state of the reticle is different from the second state of the reticle, and the modelled deformation of the reticle at the start of the second time period is based on the modelled deformation of the reticle at the end of the first time period.

In step 707, the method controls the operation of a lithographic process in dependence on the modelled deformation of the reticle.

In step 709, the method ends.

Embodiments include a number of modifications and variations to the above-described techniques.

The reticle deformation model according to embodiments is not restricted to being a FEM. Embodiments include any type of reticle deformation model that models the different conditions of a reticle 300 when the reticle 300 is clamped and unclamped.

The reticle deformation model according to embodiments may be used on its own or in conjunction with any technique for measuring the deformation of the reticle.

In FIG. 6, the y-axis shows the magnitude of the modelled deformation of the reticle shape. A related metric to the modelled deformation of the reticle shape, that is used for the y-axis in FIG. 5, is the expected magnitude of overlay error caused by the deformation of the reticle 300 if processes for correcting this source of overlay error are not performed. The effect of the improved modelling by embodiments may alternatively be demonstrated with such a related metric.

Although embodiments are described with reference to EUV systems, embodiments may be applied to any type of lithographic system. In particular, embodiments may be applied to DUV systems.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track unit (a tool that typically applies a layer of resist to a substrate and develops the exposed resist), a metrology unit and/or an inspection unit. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of aspects in the context of optical lithography, it will be appreciated that aspects may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself may be patterned and materials added on top of it may also be patterned, or may remain without patterning.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

Although specific reference may be made in this text to the use of the apparatus and/or system in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific aspects have been described above, it will be appreciated that the aspects may be practiced otherwise than as described. The description is not intended to limit the scope of the claims.

It is to be appreciated that the Detailed Description section, and not the Summary and Abstract sections, is intended to be used to interpret the claims. The Summary and Abstract sections may set forth one or more but not all exemplary aspects as contemplated by the inventor(s), and thus, are not intended to limit the aspects and the appended claims in any way.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

Embodiments include the following numbered clauses:
1. A computer system configured to:
   model, using boundary conditions that are dependent on a first state of a reticle during a first time period, the deformation of the reticle during the first time period;
   model, using boundary conditions that are dependent on a second state of the reticle during a second time period, the deformation of the reticle during the second time period; and
   control the operation of a lithographic process in dependence on the modelled deformation of the reticle,
      wherein:
         the first state of the reticle is different from the second state of the reticle; and
         the modelled deformation of the reticle at the start of the second time period is based on the modelled deformation of the reticle at the end of the first time period.
2. The computer system according to clause 1, wherein the computer system is further configured to model, using boundary conditions that are dependent on the first state of the reticle during a third time period, the deformation of a reticle during the third time period, wherein the modelled deformation of the reticle at the start of the third time period is based on the modelled deformation of the reticle at the end of the second time period.
3. The computer system according to clause 2, wherein:
   the second time period starts substantially when the first time period ends; and
   the third time period starts substantially when the second time period ends.
4. The computer system according to any preceding clause, wherein the state of the reticle during the first time period is a clamped state; and the state of the reticle during the second time period is an unclamped state.
5. The computer system according to any preceding clause, wherein the computer system is further configured to:
   obtain, prior to the first time period, a measurement of the deformation of the reticle;
   determine, in dependence on the measured deformation, an initial reticle deformation; and
   model the deformation of the reticle during the first time period in dependence on the initial reticle deformation.
6. The computer system according to clause 5, wherein the computer system is further configured to model the deformation of the reticle during all time periods between said measurement of the deformation of the reticle and a later measurement of the deformation of the reticle.
7. The computer system according to clause 5 or 6, wherein each obtained measurement of the deformation of the reticle is dependent on one or more reticle alignment measurements of the reticle.
8. The computer system according to any preceding clause, wherein said control of the operation of a lithographic process in dependence on the modelled deformation of the reticle comprises the computer system being configured to:
   determine, in dependence on the modelled deformation of the reticle, changes to the operating parameters of the lithographic process so as to at least partially reduce the effect of the modelled deformation; and
   apply the determined changes to the operating parameters of the lithographic process.
9. The computer system according to any preceding clause, wherein the computer system is configured to perform the modelling during each time period with a thermomechanical finite element model.
10. A method comprising:
   modelling, using boundary conditions that are dependent on a first state of a reticle during a first time period, the deformation of the reticle during the first time period;
   modelling, using boundary conditions that are dependent on a second state of the reticle during a second time period, the deformation of the reticle during the second time period; and
controlling the operation of a lithographic process in dependence on the modelled deformation of the reticle;
   wherein:
   the first state of the reticle is different from the second state of the reticle; and
   the modelled deformation of the reticle at the start of the second time period is based on the modelled deformation of the reticle at the end of the first time period.
11. The method according to clause 10, further comprising modelling, using boundary conditions that are dependent on the first state of the reticle during a third time period, the deformation of a reticle during the third time period;
   wherein the modelled deformation of the reticle at the start of the third time period is based on the modelled deformation of the reticle at the end of the second time period.
12. The method according to clause 11, wherein:
   the second time period starts substantially when the first time period ends; and
   the third time period starts substantially when the second time period ends.
13. The method according to any of clauses 10 to 12, wherein the state of the reticle during the first time period is a clamped state; and the state of the reticle during the second time period is an unclamped state.
14. The method according to any of clauses 10 to 13, further comprising:
   measuring, prior to the first time period, the deformation of the reticle;
   determining, in dependence on the measured deformation, an initial reticle deformation; and
   modelling the deformation of the reticle during the first time period in dependence on the initial reticle deformation.
15. The method according to clause 14, further comprising modelling the deformation of the reticle during all time periods between said measurement of the deformation of the reticle and a later measurement of the deformation of the reticle.
16. The method according to any of clauses 14 or 15, wherein each measurement of the deformation of the reticle is dependent on one or more reticle alignment measurements of the reticle.
17. The method according to any of clauses 10 to 16, wherein controlling the operation of a lithographic process in dependence on the modelled deformation of the reticle comprises: determining, in dependence on the modelled deformation of the reticle, changes to the operating parameters of the lithographic process so as to at least partially reduce the effect of the modelled deformation; and
   applying the determined changes to the operating parameters of the lithographic process.
18. The method according to any of clauses 10 to 17, wherein the modelling during each time period is performed with a thermomechanical finite element model.
19. A system comprising:
   a computer system according to any of clauses 1 to 9; and
   a lithographic apparatus;
   wherein the computer system is configured to control the operation of lithographic apparatus.
20. A device manufacturing method using a lithographic process, the device manufacturing method comprising the method according to any of clauses 10 to 18.
21. A non-transitory computer readable medium program comprising computer readable instructions configured to cause a processor to control a lithographic apparatus according to the method of any of clauses 10 to 18.

The breadth and scope of the aspects should not be limited by any of the above-described exemplary aspects, but should be defined only in accordance with the following claims and their equivalents.

1. A computer system configured to at least:
model, using boundary conditions that are dependent on a first state of a reticle during a first time period, deformation of the reticle during the first time period;
model, using boundary conditions that are dependent on a second state of the reticle during a second time period, deformation of the reticle during the second time period; and
control the operation of a lithographic process in dependence on the modelled deformation of the reticle,
wherein:
the first state of the reticle is different from the second state of the reticle; and
the modelled deformation of the reticle at the start of the second time period is based on the modelled deformation of the reticle at the end of the first time period.

2. The computer system according to claim 1, further configured to model, using boundary conditions that are dependent on the first state of the reticle during a third time period, deformation of the reticle during the third time period, wherein the modelled deformation of the reticle at the start of the third time period is based on the modelled deformation of the reticle at the end of the second time period, and wherein:
the second time period starts substantially when the first time period ends; and
the third time period starts substantially when the second time period ends.

3. The computer system according to claim 1, wherein the state of the reticle during the first time period is a clamped state; and
the state of the reticle during the second time period is an unclamped state.

4. The computer system according to claim 1, further configured to:
obtain, prior to the first time period, a measurement of the deformation of the reticle;
determine, in dependence on the measured deformation, an initial reticle deformation;
model the deformation of the reticle during the first time period in dependence on the initial reticle deformation; and
model the deformation of the reticle during all time periods between the measurement of the deformation of the reticle and a later measurement of the deformation of the reticle, each obtained measurement of the deformation of the reticle is dependent on one or more reticle alignment measurements of the reticle.

5. The computer system according to claim 1, wherein the control of the operation of a lithographic process in dependence on the modelled deformation of the reticle comprises the computer system being configured to:
determine, in dependence on the modelled deformation of the reticle, change to one or more operating parameters of the lithographic process so as to at least partially reduce the effect of the modelled deformation; and
apply the determined change to the one or more operating parameters of the lithographic process.

6. The computer system according to claim 1, configured to perform the modelling during each time period with a thermomechanical finite element model.

7. A method comprising:
modelling, using boundary conditions that are dependent on a first state of a reticle during a first time period, deformation of the reticle during the first time period;
modelling, using boundary conditions that are dependent on a second state of the reticle during a second time period, deformation of the reticle during the second time period; and
controlling the operation of a lithographic process in dependence on the modelled deformation of the reticle,
wherein:
the first state of the reticle is different from the second state of the reticle; and
the modelled deformation of the reticle at the start of the second time period is based on the modelled deformation of the reticle at the end of the first time period.

8. The method according to claim 7, further comprising modelling, using boundary conditions that are dependent on the first state of the reticle during a third time period, deformation of the reticle during the third time period, wherein the modelled deformation of the reticle at the start of the third time period is based on the modelled deformation of the reticle at the end of the second time period, wherein:
the second time period starts substantially when the first time period ends; and
the third time period starts substantially when the second time period ends.

9. The method according to claim 7, wherein the state of the reticle during the first time period is a clamped state; and
the state of the reticle during the second time period is an unclamped state.

10. The method according to claim 7, further comprising:
measuring, prior to the first time period, deformation of the reticle;
determining, in dependence on the measured deformation, an initial reticle deformation;
modelling the deformation of the reticle during the first time period in dependence on the initial reticle deformation; and
modelling the deformation of the reticle during all time periods between said measurement of the deformation of the reticle and a later measurement of the deformation of the reticle, wherein each measurement of the deformation of the reticle is dependent on one or more reticle alignment measurements of the reticle.

11. The method according to claim 7, wherein controlling the operation of a lithographic process in dependence on the modelled deformation of the reticle comprises:
determining, in dependence on the modelled deformation of the reticle, change to one or more operating parameters of the lithographic process so as to at least partially reduce the effect of the modelled deformation; and
applying the determined change to the one or more operating parameters of the lithographic process.

12. The method according to claim 7, wherein the modelling during each time period is performed with a thermomechanical finite element model.

13. A system comprising:
the computer system according to claim 1; and
a lithographic apparatus,
wherein the computer system is configured to control the operation of lithographic apparatus.

14. A device manufacturing method using a lithographic process, the device manufacturing method comprising the method according to claim 7.

15. A non-transitory computer readable medium program comprising computer readable instructions configured to cause one or more processors to at least:
model, using boundary conditions that are dependent on a first state of a reticle during a first time period, deformation of the reticle during the first time period;
model, using boundary conditions that are dependent on a second state of the reticle during a second time period, deformation of the reticle during the second time period; and
control the operation of a lithographic process in dependence on the modelled deformation of the reticle,
wherein:
the first state of the reticle is different from the second state of the reticle; and
the modelled deformation of the reticle at the start of the second time period is based on the modelled deformation of the reticle at the end of the first time period.

16. The computer readable medium program of claim 15, wherein the state of the reticle during the first time period is a clamped state; and
the state of the reticle during the second time period is an unclamped state.

17. The computer readable medium program of claim 15, wherein the instructions are further configured to cause the one or more processors to model, using boundary conditions that are dependent on the first state of the reticle during a third time period, deformation of the reticle during the third time period, wherein the modelled deformation of the reticle at the start of the third time period is based on the modelled deformation of the reticle at the end of the second time period, and wherein:
the second time period starts substantially when the first time period ends; and
the third time period starts substantially when the second time period ends.

18. The computer readable medium program of claim 15, wherein the instructions are further configured to cause the one or more processors to:
obtain, prior to the first time period, a measurement of deformation of the reticle;
determine, in dependence on the measured deformation, an initial reticle deformation;
model the deformation of the reticle during the first time period in dependence on the initial reticle deformation; and
model the deformation of the reticle during all time periods between the measurement of the deformation of the reticle and a later measurement of the deformation of the reticle, each obtained measurement of the deformation of the reticle is dependent on one or more reticle alignment measurements of the reticle.

19. The computer readable medium program of claim 15, wherein the instructions configured to control the operation of a lithographic process in dependence on the modelled deformation of the reticle are further configured to cause the one or more processors to:
determine, in dependence on the modelled deformation of the reticle, change to one or more operating parameters of the lithographic process so as to at least partially reduce the effect of the modelled deformation; and
apply the determined change to the one or more operating parameters of the lithographic process.

20. The computer readable medium program of claim 15, wherein the instructions are further configured to cause the one or more processors to perform the modelling during each time period with a thermomechanical finite element model.
